(19) United States
(12) Patent Application Publication
(10) Pub. No.: US 2024/0371822 A1
(43) Pub. Date: Nov. 7, 2024

(54) INTEGRATED CIRCUIT PACKAGE AND METHOD

(71) Applicant: Taiwan Semiconductor Manufacturing Co., Ltd., Hsinchu (TW)

(72) Inventors: Chen-Sheng Lin, Taoyuan City (TW); Chao-Wen Shih, Zhubei City (TW); Kuo-Chiang Ting, Hsinchu (TW); Yen-Ming Chen, Chu-Pei City (TW)

(21) Appl. No.: 18/459,171

(22) Filed: Aug. 31, 2023

Related U.S. Application Data
(60) Provisional application No. 63/499,513, filed on May 2, 2023.

(51) Int. Cl. H01L 23/00; H01L 21/66

(52) U.S. Cl. CPC H01L 24/96; H01L 22/12; H01L 24/08; H01L 2224/08145; H01L 2224/96

(57) ABSTRACT

A method includes: forming first semiconductor dies in a first wafer, each die of the first semiconductor dies comprising: first active devices over a front-side of a first semiconductor substrate; performing first probe tests on the first wafer; based on the first probe tests, classifying each die of the first semiconductor dies as a first good die, a first marginal die, or a first bad die; forming second semiconductor dies in a second wafer; performing second probe tests on the second wafer; based on the second probe tests, classifying each die of the second semiconductor dies as a second good die, a second marginal die, or a second bad die; and bonding the second wafer to the first wafer, each die of the first semiconductor dies aligning with a corresponding die of the second semiconductor dies.

### PRIORITY CLAIM AND CROSS-REFERENCE

This application claims the benefit of U.S. Provisional Application No. 63/499,513, filed on May 2, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and 1C illustrate cross-sectional and top-down views of intermediate steps in the formation of a semiconductor die according to some embodiments.

FIGS. 2A, 2B, and 2C illustrate cross-sectional and plan views of intermediate steps in the formation of a semiconductor die according to some embodiments.

FIGS. 3A, 3B, 3C, 4A, 4B, 4C, 5A, 5B, 5C, 6A, 6B, 6C, 7A, 7B, and 7C illustrate cross-sectional views of intermediate steps in the formation of a semiconductor package according to some embodiments.

FIG. 7D illustrates a plan view of semiconductor packages of a multi-chip module according to some embodiments.

FIGS. 8A, 8B, and 8C illustrate cross-sectional and top-down views of intermediate steps in the formation of semiconductor dies according to some embodiments.

FIGS. 9A, 9B, 10A, 10B, 11A, 11B, 12A, and 12B illustrate cross-sectional views of intermediate steps in the formation of semiconductor packages according to some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, semiconductor dies may be bonded together to form a semiconductor package, such as a 3D integrated chip (3DIC) package, which may include a system on integrated chip (SoIC) package or a system on chip (SoC) package. In particular, first semiconductor dies may be formed in a first wafer, and second semiconductor dies may be formed in a second wafer. The first wafer and the second wafer may be chip probe tested and binning processes are performed to grade, categorize, and/or classify each of the first semiconductor dies and the second semiconductor dies within the respective wafers. The first wafer and the second wafer may then be bonded to one another. As such, the first semiconductor dies are paired with corresponding second semiconductor dies. The categories associated with each electrical grouping (e.g., pairing) of semiconductor dies inform a performance category for each semiconductor package formed from those groupings (e.g., pairings). The performance categories of the semiconductor packages may then be used to determine which types of electronic devices the semiconductor packages may be incorporated within. These categories may also inform customizations in subsequent processing steps. In some embodiments, high performance semiconductor packages may be utilized in multi-chip modules (MCMs) of, for example, servers. In addition, medium performance semiconductor packages may be utilized in MCMs of, for example, gaming computers. Further, low performance semiconductor packages may be utilized in MCMs of, for example, children's toys. Moreover, only a small proportion of the semiconductor packages may be rejected wholesale. However, the disclosed embodiments allow for semiconductor dies that may otherwise not meet certain performance threshold to be utilized in functional semiconductor packages. As a result, sufficiently functional semiconductor packages may be fabricated at a higher yield, thereby reducing costs and increasing output.

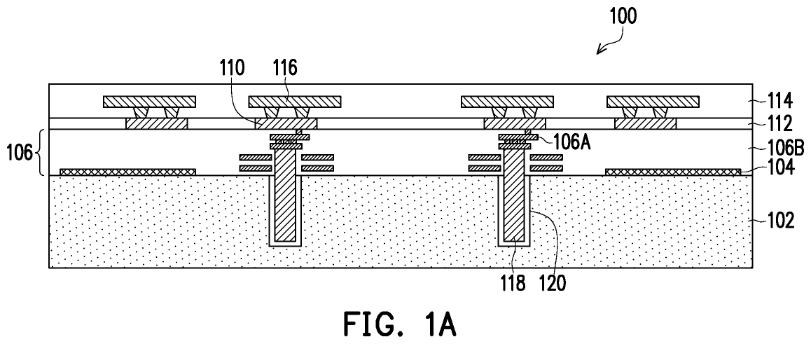

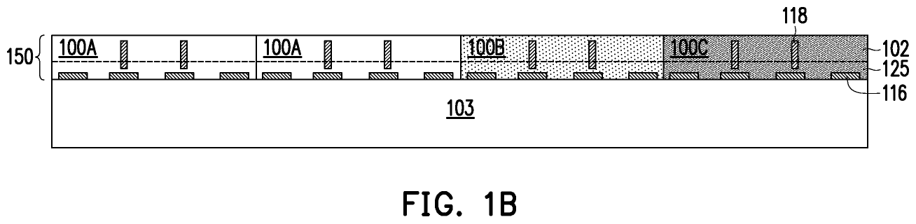

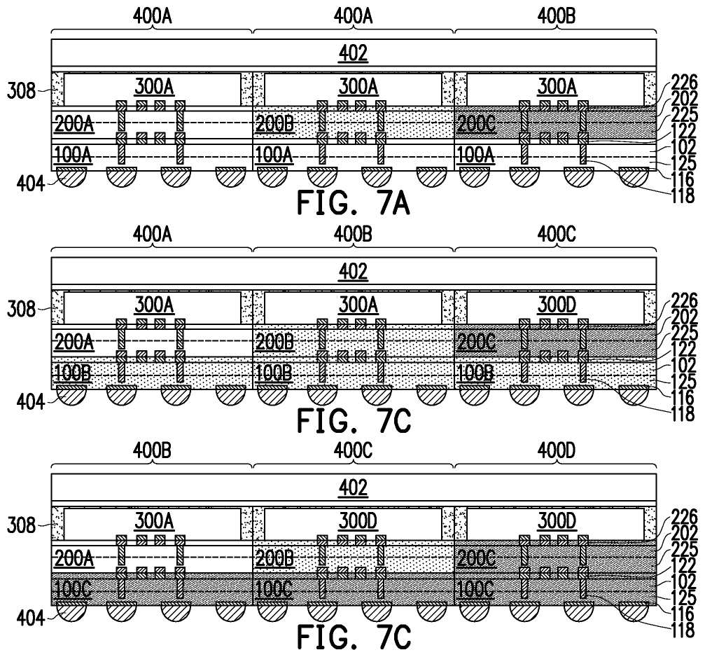

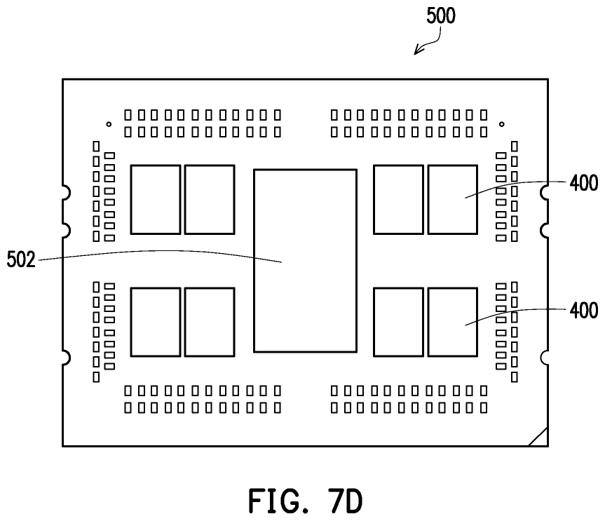

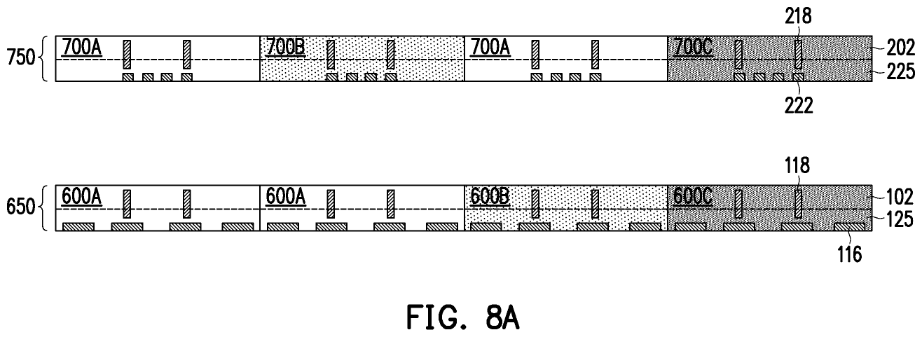

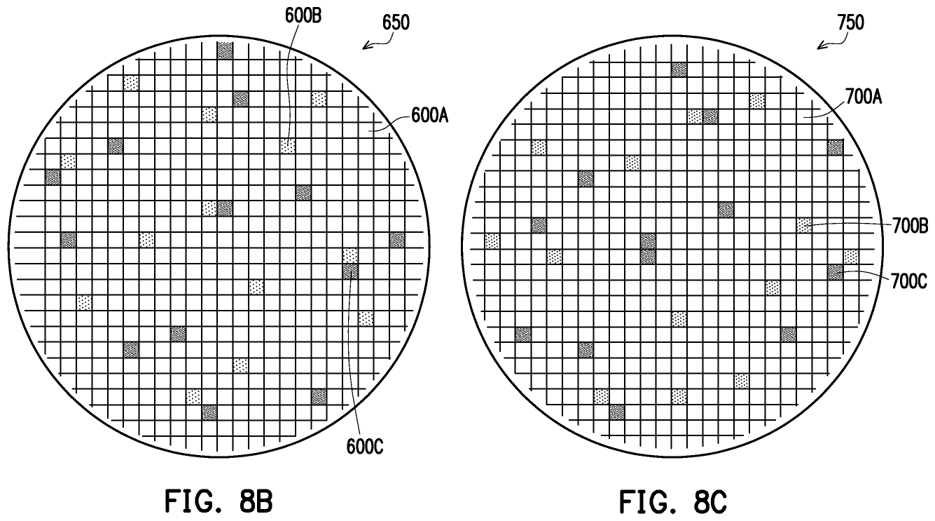

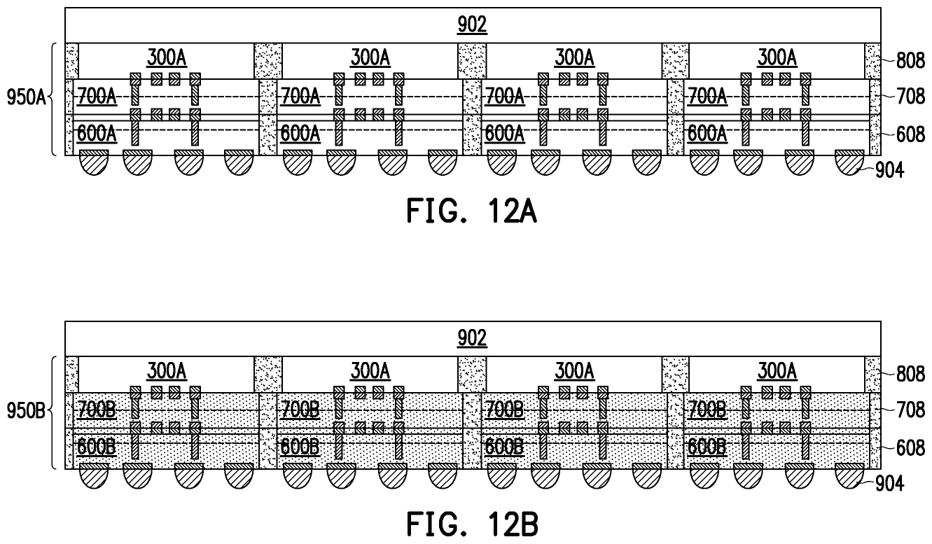

FIGS. 1A through 7D illustrate intermediate steps for forming a semiconductor package 400 (see FIGS. 7A-C) to be used, for example, in a multi-chip module (see FIG. 7D), in accordance with some embodiments. The semiconductor package 400 may include two or more tiers of dies, such as three tiers discussed below. For example, a first tier and a second tier (e.g., collectively comprising a unit of multiple cores) may be formed at the wafer level, the wafers of the first and second tiers may be bonded together. Optionally, a third tier of singulated dies may then be attached to form the semiconductor package 400. FIGS. 8 through 12 illustrate steps for forming a semiconductor package 900 (see FIG. 12) in accordance with some embodiments. Similarly, the semiconductor package 900 may include two or more tiers of dies, such as three tiers discussed below. However, the first tier and second tier may be singulated into individual semiconductor dies before forming the semiconductor package 900 as a reconstructed wafer. Optionally, a third tier of singulated dies may then be attached to form the semiconductor package 900.

In FIGS. 1A-1C, a semiconductor die 100 is part of the first tier of the semiconductor package 400. The semiconductor die 100 may be a bare chip semiconductor die (e.g., unpackaged semiconductor die) that is formed as part of a wafer 150. For example, the semiconductor die 100 may be a logic die (e.g., application processor (AP), central processing unit, microcontroller, etc.), a memory die (e.g., dynamic random access memory (DRAM) die, hybrid memory cube (HBC), a static random access memory (SRAM) die, a wide input/output (wideIO) memory die, a magnetoresistive random access memory (mRAM) die, a resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like. In accordance with various embodiments, the semiconductor die 100 is a logic die containing a plurality of cores.

The semiconductor die 100 may be processed according to applicable manufacturing processes to form integrated circuits in the semiconductor die 100. For example, the semiconductor die 100 may include a substrate 102 (e.g., a semiconductor substrate), such as silicon, doped or undoped, or an active layer of a semiconductor-on-insulator (SOI) substrate. The semiconductor substrate 102 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Referring to FIG. 1A, active and/or passive devices, such as transistors, diodes, capacitors, resistors, etc., may be formed in and/or on a front-side of the semiconductor substrate 102. The devices may be interconnected by an interconnect structure 106 (e.g., over the front-side of the semiconductor substrate 102) comprising, for example, metallization patterns 1o6A in one or more dielectric layers 1o6B on the semiconductor substrate 102. The interconnect structures 106 electrically connect the devices on the substrate 102 to form one or more integrated circuits.

The semiconductor die 100 further includes through vias 118, which may be electrically connected to the metallization patterns 1o6A in the interconnect structure 106. The through vias 118 may comprise a conductive material (e.g., copper, or the like) and may extend from the interconnect structure 106 into the substrate 102. One or more insulating barrier layers 120 may be formed around at least portions of the through vias 118 in the substrates 102. The insulating barrier layers 120 may comprise, for example, silicon oxide, silicon nitride, silicon oxynitride, or the like, and may be used to physically and electrically isolate the through vias 118 from the substrate 102. In subsequent processing steps, the substrate 102 may be thinned to expose the through vias 118 to provide electrical connection from a back side of the substrate 102 to a front side of the substrate 102. In various embodiments, the backside of the substrate 102 may refer to a side of the substrate 102 opposite to the devices and the interconnect structure 106 while the front-side of the substrate 102 may refer to a side of the substrate 102 on which the devices and the interconnect structure 106 are disposed.

The semiconductor die 100 further comprises contact pads 110, which allow connections to be made to the interconnect structure 106 and the devices on the substrate 102. The contact pads 110 may comprise copper, aluminum, or another conductive material. A passivation film 112 is disposed on the interconnect structure 106, and the contact pads 110 are exposed at a top surface of the passivation film 112. The passivation film 112 may comprise silicon oxide, silicon oxynitride, silicon nitride, or the like. In some embodiments, the contact pads 110 may extend above a top surface of the passivation film 112.

Referring also to FIGS. 1B and 1C, the semiconductor die 100 may be formed as part of a larger wafer 150. In accordance with some embodiments, the semiconductor die 100 may be packaged while still connected as part of the wafer 150. In other embodiments, the semiconductor die 100 may be packaged after it has been singulated from other components of the wafer (see FIGS. 8A-12B).

In accordance with various embodiments, a chip probe test is performed on each of the semiconductor dies 100 (e.g., through the contact pads 110) of the wafer 150. A binning process is performed to categorize the semiconductor dies 100 based on the results of the chip probe tests. The chip probe test checks electrical functionality of the semiconductor die 100, and semiconductor dies 100A that pass the chip probe tests are categorized as known good dies (KGDs) 100A. Conversely, some of the semiconductor dies 100B may be below a performance threshold of functionality except that being subsequently paired with a die from the second tier being above the performance threshold may render the stack of dies sufficiently functional. As such, these semiconductor dies 100B are categorized as marginal performance dies (MPDs) 100B. Semiconductor dies 100C that do not pass the chip probe tests and could not be reliably paired with a second tier die are eventually discarded. These semiconductor dies 100C are categorized as known bad dies (KBDs) 100C. In this manner, all of the KGDs 100A as well as some of the MPDs 100B will be utilized in functional semiconductor packages 400 (e.g., setting aside other factors that may cause a semiconductor package 400 to fall below a performance threshold requirement). As a result, the fabrication yield is improved for semiconductor dies 100 that may be packaged into functional semiconductor packages 400.

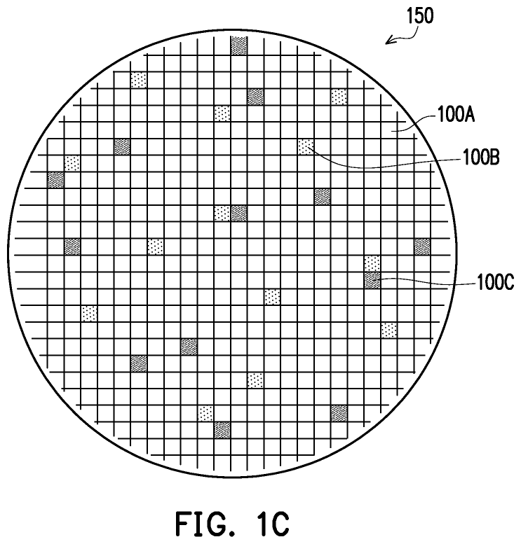

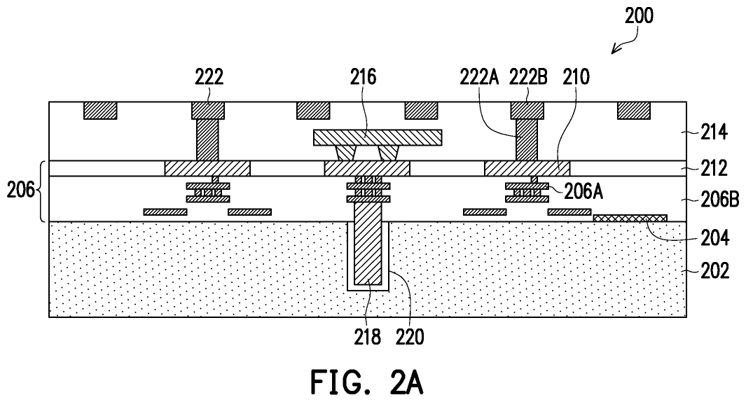

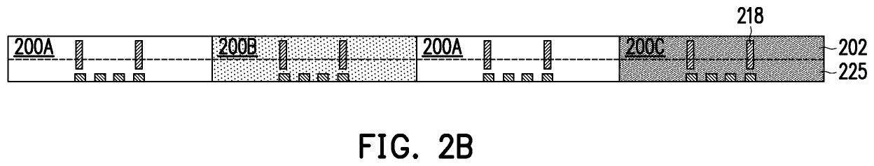

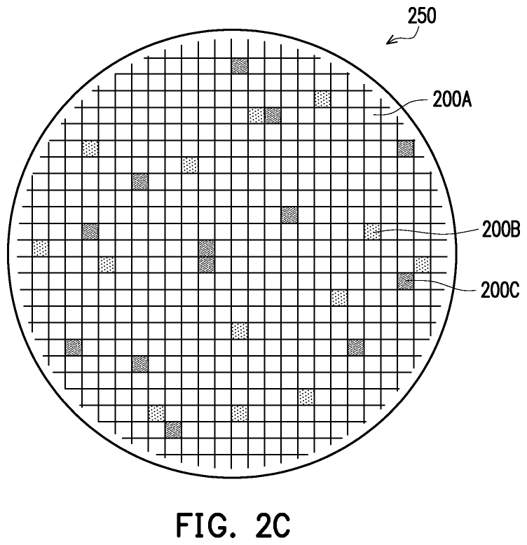

As discussed above, the binning process involves categorizing or classifying the semiconductor dies 100 based on the results of the chip probe tests. In accordance with some embodiments, the semiconductor dies 100 may be categorized based on their number of functional cores. For example, each of the semiconductor dies 100 may include, e.g., eight cores such that any number from 0 to 8 of the cores may be deemed functional. For the sake of example, the binning process may further include assigning an upper range of functional cores as pertaining to a KGD (e.g., 6 to 8 functional cores), an intermediate number of functional cores as pertaining to an MPD (e.g., 3 to 5 functional cores), and a lower range of functional cores as pertaining to a KBD (e.g., 0 to 2 functional cores). As discussed in greater detail below, these categorizations from the binning process will be subsequently used in conjunction with categorizations from a binning process performed on the second tier dies (see FIGS. 2A-2C).

After the chip probe tests, a dielectric layer 114 is formed over the contact pads 110 and the interconnect structure 106 of each semiconductor die 100. The dielectric layer 114 may comprise silicon oxide, silicon oxynitride, silicon nitride, or the like. The dielectric layer 114 may protect the contact pads 110 during subsequent packaging processes. In some embodiments, additional interconnection between the contact pads 110 may be provided by metallization patterns 116 (e.g., including metal pads and metal vias), which are disposed in the dielectric layer 114.

FIG. 1B illustrates an exemplary subset of the semiconductor dies 100 of the wafer 150, wherein the illustration is simplified such that the substrate 102 and most of the non-substrate features 125 (e.g., the active/passive devices and various conductive and dielectric features) are distinguished by a dotted line. As illustrated, some of the semiconductor dies 100 will be KGDs 100A, some will be MPDs 100B, and some will be KBDs 100C.

FIG. 1C illustrates an exemplary plan view of the semiconductor dies 100 of the wafer 150, wherein the illustration is simplified to distinguish between device regions containing each of the semiconductor dies 100. Note that the number of illustrated semiconductor dies 100 is solely intended for the sake of example, and any suitable number may be included in the wafer 150. In some embodiments, the MPDs 100B and the KBDs 100C may be scattered among a majority being the KGDs 100A. For example and for the sake of current and subsequent discussion, the KGDs 100A may represent about 80% of the wafer 150, the MPDs 100B may represent about 10% of the wafer 150, and the KBDs 100C may represent about 10% of the wafer 150. As noted above and discussed in greater detail below, instead of only the 80% of the semiconductor dies 100 (e.g., the KGDs 100A) being useful in functional semiconductor packages 400, embodiments described herein allow for up to 90% of the semiconductor dies 100 (e.g., all of the KGDs 10A and some of the MPDs 100B) being useful in functional semiconductor packages 400.

In FIGS. 2A-2C, a second semiconductor die 200 that will be subsequently bonded to the semiconductor die 100 is part of the second tier of the semiconductor package 400. In accordance with various embodiments, the semiconductor die 200 is a same type of die as the semiconductor die 100, such as a logic die containing a plurality of cores. As discussed below, the semiconductor die 100 and a corresponding semiconductor die 200 may be packaged together (e.g., in a double tiered stack configuration) to form a core unit. The materials and formation processes of the features in the semiconductor die 200 may be found by referring to the like features in the semiconductor die 100, with the like features in the semiconductor die 100 starting with number “1,” which features correspond to the features in the semiconductor die 200 and having reference numerals starting with number “2.”

For example, the semiconductor die 200 may include a semiconductor substrate 202 having active and/or passive devices (e.g., transistors, capacitors, diodes, resistors, or the like) formed thereon and an interconnect structure 206. The interconnect structure 206 includes metallization patterns 206A in one or more dielectric layers 206B, and the metallization patterns 206A electrically connects the devices on the substrate 200 into functional circuits. The interconnect structure 206 further includes a passivation layer 212 and contact pads 210 that are electrically connected to the metallization patterns 206A. A dielectric layer 214 may be disposed over the contact pads 210 and the passivation layer 212. Metallization patterns 216 (e.g., including metal pads and metal vias) may provide interconnection between the bond pads 210 within the dielectric layer 214. In addition, through vias 218 with barrier layers 220 may extend from a front-side of the semiconductor die 200 and partially through the semiconductor substrate 202.

The semiconductor die 200 may further include connection structures 222 (e.g., comprising bond pads 222A and bond pad vias 222B) in the dielectric layer 214. The bond pads 222A are electrically connected to the contact pads 210 by the bond pad vias 222B, and the contact pads 210 may electrically connect the connection structures 222 to the circuits of the semiconductor die 200. The bonding pads 222A and the bond pad vias 222B may be formed by a damascene process, for example, and a planarization process may be performed to level top surfaces of the connection structures 222 with the dielectric layer 214. In some embodiments (not specifically illustrated), the semiconductor die 200 may not include the through vias 218 that extend into the substrate 202.

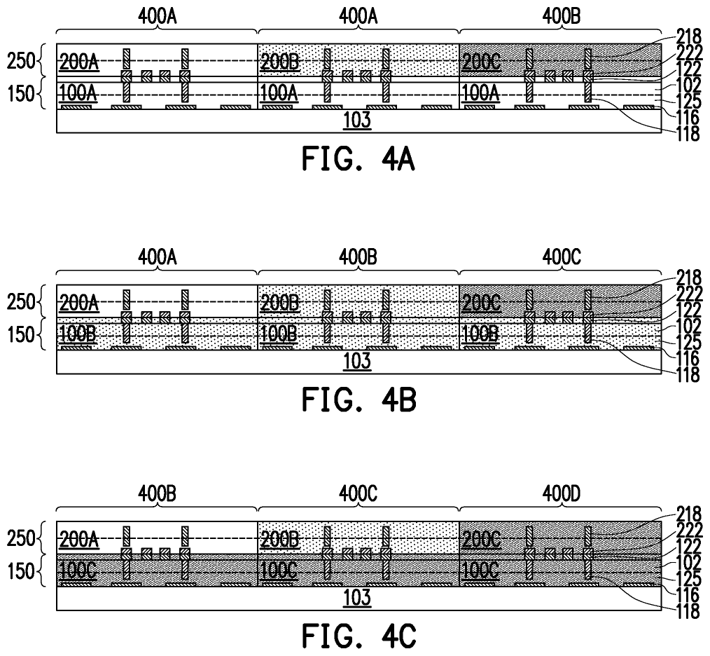

In accordance with various embodiments, the semiconductor die 200 is formed substantially the same as the semiconductor die 100, except with the differences described above (e.g., the bond pad vias 222A and the bond pads 222B). For example, the semiconductor die 200 may be fabricated with a same number of cores (e.g., 8 cores), which may be used for a binning process performed on the semiconductor die 200, as discussed in greater detail below. In some embodiments, the semiconductor die 200 may also be formed initially as part of a wafer 250 comprising a plurality of the semiconductor dies 200. In some embodiments (see FIGS. 4A-4C) the wafer 250 is bonded while the wafer 150 in a wafer on wafer (WoW) packaging process. Other packaging processes may be used in other embodiments.

In accordance with various embodiments, a chip probe test is performed on each of the semiconductor dies 200 of the wafer 250, similarly as described above in connection with the semiconductor dies 100. In addition, a binning process may be performed to categorize the semiconductor dies 200 based on the results of the chip probe tests, similarly as described above in connection with the semiconductor dies 100. As such, the semiconductor dies 200 are also categorized as KGDs 200A, MPDs 200B, and KBDs 200C. In addition, for the sake of continuing the example pertaining to the semiconductor dies 100, each of the semiconductor dies 200 may also include, e.g., eight cores such that any number from 0 to 8 of the cores may be deemed functional. Further, the binning process may further include assigning an upper range of functional cores as pertaining to a KGD (e.g., 6 to 8 functional cores), an intermediate number of functional cores as pertaining to an MPD (e.g., 3 to 5 functional cores), and a lower range of functional cores as pertaining to a KBD (e.g., 0 to 2 functional cores). As noted above, these categorizations from this binning process of the semiconductor dies 200 will be used in conjunction with the categorizations from the binning process of the semiconductor dies 100 (see FIGS. 1A-1C).

After the chip probe tests, a dielectric layer 214 is formed over the contact pads 210 and the interconnect structure 206 of each semiconductor die 200. The dielectric layer 214 may comprise silicon oxide, silicon oxynitride, silicon nitride, or the like. The dielectric layer 214 may protect the contact pads 210 during subsequent packaging processes. In some embodiments, additional interconnection between the contact pads 210 may be provided by metallization patterns 216, which are disposed in the dielectric layer 214.

FIG. 2B illustrates an exemplary subset of the semiconductor dies 200 of the wafer 250, wherein the illustration is simplified such that the substrate 202 and most of the non-substrate features 225 (e.g., the active/passive devices and various conductive and dielectric features) are distinguished by a dotted line. As illustrated, some of the semiconductor dies 200 will be KGDs 200A, some will be MPDs 200B, and some will be KBDs 200C.

FIG. 2C illustrates an exemplary plan view of the semiconductor dies 200 of the wafer 250, wherein the illustration is simplified to distinguish between device regions containing each of the semiconductor dies 200. Note that the number of illustrated semiconductor dies 200 is solely intended for the sake of example, and any suitable number may be included in the wafer 250. In some embodiments, the MPDs 200B and the KBDs 200C may be scattered among a majority being the KGDs 200A. To continue the example from above and for the sake of discussion, the KGDs 200A may represent about 80% of the wafer 250, the MPDs 200B may represent about 10% of the wafer 250, and the KBDs 200C may represent about 10% of the wafer 250. Similarly as discussed in connection with the wafer 150, instead of only the 80% of the semiconductor dies 200 (e.g., the KGDs 200A) being useful in functional semiconductor packages 400, embodiments described herein allow for up to 90% of the semiconductor dies 200 (e.g., all of the KGDs 200A and some of the MPDs 200B) being useful in functional semiconductor packages 400.

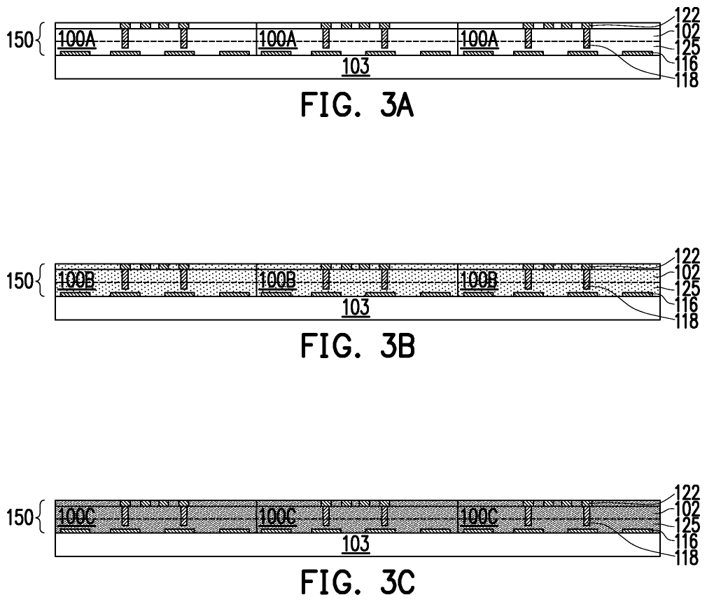

FIGS. 3A-7D illustrate packaging the wafer 150 with the wafer 250 (along with additional semiconductor dies) to form semiconductor packages 400 and, optionally, subsequently incorporated into a multi-chip module 500. The figures also show a variety of combinations of the semiconductor dies 100 and the semiconductor dies 200, in accordance with various embodiments. While in some embodiments (not specifically illustrated) the semiconductor packages 400 may be manufactured with only one of the semiconductor dies 100, 200, embodiments herein achieve advantages by forming the semiconductor packages 400 with both of the semiconductor dies 100, 200 in a stacked configuration (e.g., a double tiered core unit). Referring again to FIGS. 1C and 2C showing scattered and inconsistent patterning between the dies, it should be appreciated that the KGDs 100A, the MPDs 100B, and the KBDs 100C may have a variety of pairings with the KGDs 200A, the MPDs 200B, and the KBDs 200C. In particular, the wafer 150 and the wafer 250 will be bonded to one another such that corresponding semiconductor dies 100, 200 being effectively paired to one another.

In some embodiments, a majority of the pairings of the semiconductor dies 100, 200 may contribute to a functional semiconductor package 400 (e.g., setting aside other factors). For example, substantially all pairings of a KGD 100A with any of the semiconductor dies 200 and substantially all pairings of any of the semiconductor dies 100 with a KGD 200A may have sufficient functionality (e.g., total combined functional cores). In addition, substantially all pairings of MPDs 100B, 200B may also have sufficient functionality (e.g., total combined functional cores). However, substantially all pairings of a KBD 100C, 200C with either a respective marginal performance die 100B, 200B or a respective KBD 200C, 100C may not have sufficient functionality (e.g., total combined functional cores). Note that the total combined functional cores metric provides a rough prediction of the functionality of the completed semiconductor package 400, however, post-fabrication testing will provide the actual performance metrics for the completed semiconductor package 400. Table 1 below illustrates estimated proportions of the various pairings based on the exemplary percentages of KGDs, MPDs, and KBDs in connection with estimated proportions of functional and non-functional pairings, as discussed above in connection with FIGS. 1C and 2C.

TABLE 1

| | | | | | | Non- |
|---|---|---|---|---|---|---|
| | Die | | Die | | Func- | Func- |
| | 100 | | 200 | Total | tional | tional |
| Die 100 | (%) | Die 200 | (%) | Pairings | Pairings | Pairings |
| KGD 100A | 80% | KGD 200A | 80% | 64% | 64% | |
| KGD 100A | 80% | MPD 200B | 10% | 8% | 8% | |
| KGD 100A | 80% | KBD 200C | 10% | 8% | 8% | |
| MPD 100B | 10% | KGD 200A | 80% | 8% | 8% | |
| MPD 100B | 10% | MPD 200B | 10% | 1% | 1% | |
| MPD 100B | 10% | KBD 200C | 10% | 1% | | 1% |
| KBD 100C | 10% | KGD 200A | 80% | 8% | 8% | |
| KBD 100C | 10% | MPD 200B | 10% | 1% | | 1% |
| KBD 100C | 10% | KBD 200C | 10% | 1% | | 1% |

| | | | |
|---|---|---|---|
| Summations | 100% | 97% | 3% |

As provided in Table 1, forming the semiconductor packages 400 with a stack of the semiconductor dies 100, 200 (e.g., the double tiered core unit) and using the binning processes discussed above, an otherwise expected yield of 80% KGDs may translate to greater than or equal to 90% yield (e.g., of the stacks of semiconductor dies 100, 200), or greater than or equal to 95%, such as about 97% yield. As such, the embodiments achieve a proportionate yield for the completed semiconductor packages 400. For example, instead of a 20% proportion of dies being insufficiently functional (e.g., non-KGDs) and resulting in non-functional or insufficiently functional semiconductor packages 400, less than 10% or less than 5% (e.g., about 3%) of the resulting stacks of the semiconductor dies 100, 200 (e.g., and a proportionate amount of the semiconductor packages 400) may be insufficiently functional based on the yield of the semiconductor dies 100, 200. In other words, the binning and categorization processes (e.g., with the stacked or double tiered configuration) allow for utilizing the semiconductor dies 100, 200 with lower individual performance thresholds while achieving the same or better performance as a single tiered core unit configuration in association with binning and categorization processes based solely on the KGD and non-KGD threshold.

Note that Table 1 applies exemplary proportions for each grade of semiconductor dies 100, 200 to show how the binning and classification processes achieve greater utilization, such as utilization of some of the semiconductor dies 100, 200 that may otherwise be discarded as non-KGDs. For example, the binning and categorization processes may apply to any proportions of KGDs, MPDs, and KBDs—whether the same or different between the semiconductor dies 100, 200—and whether weighted differently based on proportions of maximum cores therein (or whichever applicable metric is utilized). It should also be appreciated that the binning process and categorizations may include any suitable number of categories or grades to permit greater performance selection among varying performance levels.

As a result of both of the binning and categorization processes discussed above, the semiconductor packages 400 may also be provisionally categorized based on the particular pairings of the semiconductor dies 100, 200. For example, some of the semiconductor packages 400A may include paired KGDs 100A, 200A or KGDs 100A, 200A paired with MPDs 200B, 100B (respectively). These semiconductor packages 400A (e.g., high performance packages) may be selected for inclusion in relatively high performance and/or high reliability devices, such as servers. In addition, some of the semiconductor packages 400B may include paired MPDs 100B, 200B or KGDs 100A, 200A paired with KBDs 200C, 100C (respectively). These semiconductor packages 400B (e.g., marginal performance packages) may be selected for inclusion in relatively medium performance and/or medium reliability devices, such as gaming computers. Further, some of the semiconductor packages 400C may include MPDs 100B, 200B paired with KBDs 200C, 100C (respectively). These semiconductor packages 400C (e.g., low performance packages) may be discarded or selected for inclusion in relatively low performance and/or low reliability devices, such as children's toys. Moreover, some of the semiconductor packages 400D may include paired KBDs 100D, 200D. These semiconductor packages 400D may be rejected and discarded altogether.

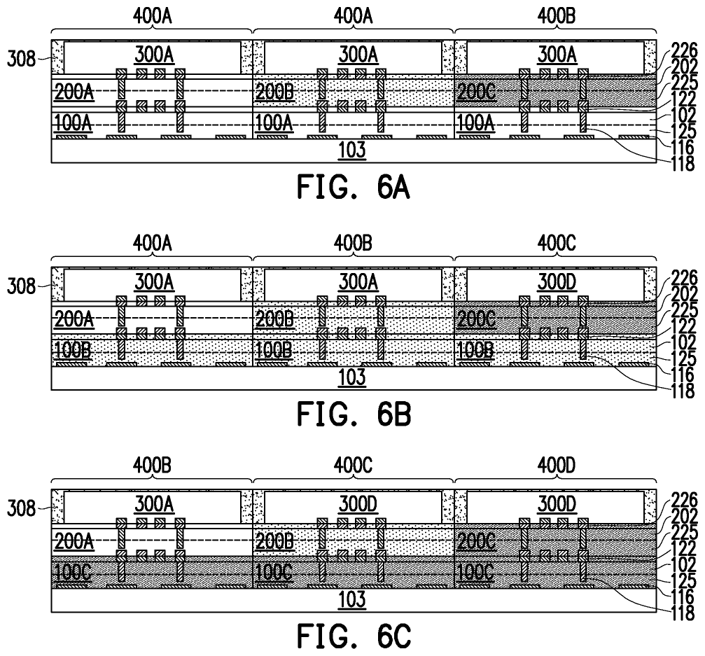

In accordance with various embodiments, subsequent processing of the semiconductor packages 400D (and, optionally, also the semiconductor packages 400C) may be adjusted or skipped in order to reduce fabrication costs and limit waste of expensive materials. For example, as discussed in greater detail below, attachment of singulated third tier dies (see FIGS. 6A-6C) may include attaching dummy dies to insufficiently functional or non-functional semiconductor packages 400C, 400D.

In FIGS. 3A-3C, a thinning process may be applied to the semiconductor die 100 (e.g., illustrated in FIGS. 1A-1C) to expose the through vias 118, and bond pads 122 are formed over the through vias 118. The thinning removes portions of the substrate 102 over the through vias 118. In some embodiments, the thinning may further remove lateral portions of the barrier layer 1o8 on the through vias 118 to expose the through vias 118. The thinning process may comprise performing a chemical mechanical polish (CMP), grinding, an etch back (e.g., a wet etch), combinations thereof, or the like. In the illustrated embodiments, the thinning process results in a backside of the remaining substrate 102 being level with a lateral surface of the through vias 118. In some embodiments (not specifically illustrated), the thinning process may recess the substrate 102 such that the through vias 118 extend beyond a back surface of the substrate 102. This can be achieved, for example, through a selective etching process that selectively etches the substrate 102 without significantly etching the through vias 118. In some embodiments, the semiconductor die 100 may be attached to a carrier substrate 103 during the thinning process and subsequent processing for increased mechanical support.

In some embodiments, a dielectric bond layer (not separately illustrated from the non-substrate features 125) is deposited over the remaining substrate 102. The dielectric bond layer may comprise silicon oxide, silicon nitride, silicon oxynitride, or the like, and the dielectric bond layer may be deposited using a suitable deposition process such as chemical vapor deposition (CVD), physical vapor deposition (PVD), atomic layer deposition (ALD), or the like. The material of the dielectric bond layer may be selected so that it is suitable for direct fusion bonding to the dielectric layer 214 in subsequent process steps (see FIGS. 4A-4C). Bond pads 122 may be formed over the substrate 102 and disposed in the dielectric bond layer. The bond pads 122 may be formed either before or after the dielectric bond layer is deposited. The bond pads 122 may comprise copper or the like and be formed by a plating process, a damascene process, or the like, for example. The bond pads 122 may be electrically connected to the devices/circuits (e.g., the components 104) of the semiconductor die 100 by the through vias 118.

Alternatively, in embodiments where the through vias 118 protrude from the back-side of the substrate 102, the bond pads 122 may be omitted, and the dielectric bond layer may be formed to surround protruding portions of the through vias 118. In such embodiments, the dielectric bond layer may be deposited to initially cover the through vias 118, and a planarization step may then be performed to substantially level surfaces of the through vias 118 and the dielectric bond layer.

In FIGS. 4A-4C, the semiconductor die 200 is bonded to the semiconductor die 100 (e.g., the wafer 250 is bonded to the wafer 150), for example, in a dielectric-to-dielectric and metal-to-metal bonding configuration to form the double tiered core units of the semiconductor packages 400. The semiconductor dies 200 of the wafer 250 are disposed face down such that a front-side of the semiconductor dies 200 face the semiconductor dies 100 and a back-side of the semiconductor dies 200 face away from the semiconductor dies 100. As such, the front-side of the semiconductor dies 200 are bonded to the bond pads 122 and the dielectric bond layer on the back-side of the semiconductor dies 100. For example, the dielectric layer 214 of the semiconductor die 200 may be directly bonded to the dielectric bond layer of the semiconductor die 100, and the bond pads 222A of the semiconductor die 200 may be directly bonded to the bond pads 122 of the semiconductor die 100. In an embodiment, the bond between the dielectric layer 214 and the dielectric bond layer may be an oxide-to-oxide bond, or the like. The bonding process further directly bonds the bond pads 222A of the semiconductor die 200 to the bond pads 122 of the semiconductor die 100 through direct metal-to-metal bonding. Thus, electrical connection between the semiconductor dies 100, 200 is provided by the physical connection of the bond pads 222A to the bond pads 122. In alternative embodiments where the bond pads 122 are omitted, the bond pads 222A may be similarly directly bonded to the through vias 118 by direct metal-to-metal bonding.

As an example bonding process starts with aligning the semiconductor dies 200 with the semiconductor dies 100 (e.g., aligning the wafer 250 with the wafer 150), for example, by first applying a surface treatment to one or more of the dielectric bond layer or the dielectric layer 214. The surface treatment may include a plasma treatment. The plasma treatment may be performed in a vacuum environment. After the plasma treatment, the surface treatment may further include a cleaning process (e.g., a rinse with deionized water, or the like) that may be applied to one or more of the dielectric bond layer or the dielectric layer 214. The bonding process may then proceed to aligning the bond pads 222A to the bond pads 122 (or the through vias 118). When the semiconductor dies 100, 200 are aligned, the bond pads 222A may overlap with the corresponding bond pads 122. Next, the bonding includes a pre-bonding step, during which the wafer 250 is put in contact with the wafer 150. The pre-bonding may be performed at room temperature (e.g., between about 21° C. and about 25° C.). The bonding process continues with performing an anneal, for example, at a temperature between about 150° C. and about 400° C. for a duration between about 0.5 hours and about 3 hours, so that the metal in bond pad 222A (e.g., copper) and the metal of the bond pads 122 (e.g., copper) inter-diffuses to each other, and hence the direct metal-to-metal bonding is formed. As illustrated, the bonded semiconductor dies 100, 200 form a stacked configuration (e.g., a double tiered core unit).

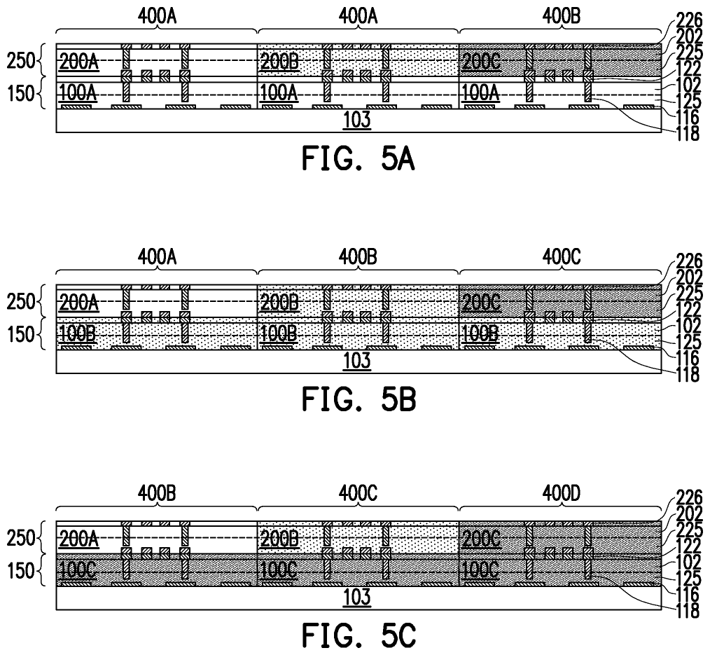

In FIG. 5, a thinning process may be applied to the semiconductor die 200 (e.g., illustrated in FIGS. 2A-2C) to expose the through vias 218, and bond pads 226 are formed over the through vias 218, similarly as described above in connection with the semiconductor die 100. The thinning removes portions of the substrate 202 over the through vias 218. In some embodiments, the thinning may further remove lateral portions of the barrier layer 208 on the through vias 118 to expose the through vias 118. The thinning process may comprise performing a CMP, grinding, an etch back (e.g., a wet etch), combinations thereof, or the like. In the illustrated embodiments, the thinning process results in a backside of the remaining substrate 202 being level with a lateral surface of the through vias 218. In some embodiments, the thinning process may recess the substrate 202 such that the through vias 218 extend beyond a back surface of the substrate 202. This can be achieved, for example, through a selective etching process that selectively etches the substrate 202 without significantly etching the through vias 218.

In some embodiments, a dielectric bond layer (not separately illustrated from the non-substrate features 225) is deposited over the remaining substrate 202. The dielectric bond layer may comprise silicon oxide, silicon nitride, silicon oxynitride, or the like, and the dielectric bond layer may be deposited using a suitable deposition process such as CVD, PVD, ALD, or the like. The material of the dielectric layer may be selected so that it is suitable for direct fusion bonding to, for example, a dielectric layer of other package components in subsequent process steps (see FIGS. 6A-6C). Bond pads 226 may be formed over the substrate 202 and disposed in the dielectric bond layer. The bond pads 226 may be formed either before or after the dielectric bond layer is deposited. The bond pads 226 may comprise copper or the like and be formed by a plating process, a damascene process, or the like, for example. The bond pads 226 may be electrically connected to the devices/circuits (the components 204) of the semiconductor die 200 by the through vias 218.

Alternatively, in embodiments where the through vias 218 protrude from the back-side of the substrate 202, the bond pads 226 may be omitted, and the dielectric bond layer may be formed to surround protruding portions of the through vias 218. In such embodiments, the dielectric bond layer may be deposited to initially cover the through vias 218, and a planarization step may then be performed to substantially level surfaces of the through vias 218 and the dielectric bond layer.

In FIGS. 6A-6C, semiconductor dies 300 are be attached to the semiconductor dies 200. The semiconductor die 300 may be a same type of die as the semiconductor dies 100, 200 or a different type of die. For example, the semiconductor die 300 may be a memory die (e.g., DRAM, HBC, SRAM, wideIO, mRAM, rRAM, etc.), a power management die (e.g., PMIC), a radio frequency (RF) die, a sensor die, a MEMS die, a signal processing die (e.g., DSP), a front-end die (e.g., AFE), a biomedical die, or the like. In accordance with various embodiments, the semiconductor die 300 is a memory die.

As illustrated, the semiconductor die 300 may be singulated from a wafer before being incorporated into the semiconductor package 400. Note that the binning processes described above allow for discretion during attachment of the semiconductor dies 300 to the semiconductor dies 200. For example, KGDs 300A (e.g., sufficient performance dies) of the semiconductor dies 300 may be attached in the semiconductor packages 400A, 400B that contain sufficiently functional double tiered stacks of the semiconductor dies 100, 200. In addition, dummy dies or KBDs 300D (e.g., insufficient performance dies) of the semiconductor dies 300 may be attached in the semiconductor packages 400C, 400D that contain non-functional (e.g., or insufficiently functional) double tiered stacks of the semiconductor dies 100, 200. Note that the dummy dies may be formed in the wafer with the other semiconductor dies 300 or separately. Due to selecting the semiconductor dies 300 based on the binning processes for the semiconductor dies 100, 200, costs are reduced by avoiding inclusion of functional semiconductor dies 300 into non-functional semiconductor packages 400. Moreover, the semiconductor dies 300 may have similar binning categories, and selection of the semiconductor dies 300 may be based on matching its category with the combined categories of the semiconductor dies 100, 200.

Still referring to FIGS. 6A-6C, an insulating material 308 is formed over the semiconductor die 200 (e.g., the wafer 250), around the semiconductor die 300. In some embodiments, the insulating material 308 is a molding compound (e.g., an epoxy, a resin, a moldable polymer, or the like) shaped or molded using for example, a mold (not shown) which may have a border or other feature for retaining insulating material 308 when applied. Such a mold may be used to pressure mold the insulating material 308 around the semiconductor die 300 to force the insulating material 308 into openings and recesses, eliminating air pockets or the like in the insulating material 308.

In some embodiments, the insulating material 308 is a dielectric comprising (e.g., an oxide, nitride, oxynitride, or the like), a polymer material (e.g., polyimide or the like), spin on glass (SOG), or the like that is deposited over the semiconductor die 300. In such embodiments, insulating material 308 may comprise be formed by PVD, CVD, or another process. In addition, the insulating material 308 may be planarized by, e.g., a grinding, CMP process, or the like. After planarization, top surfaces of the insulating material 308 and the semiconductor die 300 are substantially level.

In FIGS. 7A-7D, a carrier substrate 402 is attached over the semiconductor dies 300, the carrier substrate 103 is removed, and external connectors 404 are formed along the semiconductor dies 100 (e.g., the front-side of the wafer 150). For example, after attaching the carrier substrate 402, a carrier substrate de-bonding is performed to detach (or “de-bond”) the carrier substrate 103 from the semiconductor dies 100. In some embodiments, the de-bonding includes removing the carrier substrate 103 and adhesive or bonding layers (if present) with a suitable removal process. In some embodiments, a planarization process such as a CMP, an etch-back process, combinations thereof, or the like is utilized.

In some embodiments, a passivation layer (not specifically illustrated) is formed along the semiconductor die 100 after removing the carrier substrate 103. The passivation layer may be formed of one or more acceptable dielectric materials, such as photosensitive polymers, such as polyimide, polybenzoxazole (PBO), a benzocyclobutene (BCB) based polymer, combinations thereof, or the like. Other acceptable dielectric materials include silicon oxide, silicon nitride, low-k (LK) dielectrics such as carbon doped oxides, extremely low-k (ELK) dielectrics such as porous carbon doped silicon dioxide, combinations thereof, or the like. The passivation layer may be formed by spin coating, lamination, deposition (e.g., CVD), combinations thereof, or the like.

External connectors 404 may include under-bump metallizations (UBMs) and conductive connectors (not separately illustrated), in accordance with various embodiments. For example, the UBMs are formed in and/or over the front-side of the wafer 150 (e.g., the passivation layer) and are electrically coupled to the metallization patterns 116. For example, before forming the external connectors 404, openings may first be formed in the passivation layer and the dielectric layer 114 to expose the metallization patterns 116, and conductive features (not specifically illustrated) may be formed in the openings. The external connectors 404 may then be formed over these conductive features and include conductive pillars, pads, or the like, to which external connections can be made. In some embodiments, the external connectors 404 include bond pads at or near an exposed surface of the passivation layer, and the conductive features may be bond pad vias that connect the bond pads (e.g., the external connectors 404) to the metallization patterns 116. In various embodiments, the external connectors 404 and the conductive features (e.g., the bond pads and the bond pad vias, respectively) may be formed by a damascene process, such as single damascene processes, a dual damascene process, or the like. The external connectors 404 can be formed of a conductive material, such as a metal, such as copper, aluminum, or the like, which can be formed by, for example, plating, or the like. In some embodiments, a planarization process such as a CMP, an etch-back process, combinations thereof, or the like is performed on the external connectors 404. After the planarization process, surfaces of the external connectors 404 and the passivation layer are substantially coplanar (within process variations).

As discussed above, the external connectors 404 may further include conductive connectors, such as reflowable connectors formed on the UBMs. The conductive connectors may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors may include a conductive material such as solder, copper, aluminum, gold, nickel, silver, palladium, tin, the like, or a combination thereof. In some embodiments, the conductive connectors are formed by initially forming a layer of solder through evaporation, electroplating, printing, solder transfer, ball placement, or the like. Once a layer of solder has been formed, a reflow may be performed in order to shape the material into the desired bump shapes. In another embodiment, the conductive connectors include metal pillars (such as copper pillars) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Referring to FIG. 7D, further processing steps may be applied to the package 400, such as incorporating the semiconductor packages 400 into MCM 500. For example, one or more singulation processes may be applied to separate the semiconductor dies 100, 200, 300 from other semiconductor dies in the combined wafers. The singulation process may include sawing, dicing, a laser cutting, or the like. For example, the singulation process can include sawing the encapsulant 308, the passivation layer, the substrate 102, the interconnect structure 106, and the dielectric layer 114.

In various embodiments, the MCM 500 includes a plurality of the semiconductor packages 400. As illustrated, the MCM 500 may include eight semiconductor packages 400, and each of which includes semiconductor dies 100, 200. In addition, pertaining to the examples discussed above, each semiconductor die 100 may include 8 cores, and each semiconductor die 200 may include 8 cores. As such, a high performance MCM 500 (e.g., comprising semiconductor packages 400A) may include up to 128 functional cores or substantially close to 128 functional cores. However, it should be appreciated that these numbers may vary by design, performance threshold levels, and other suitable factors.

FIGS. 8A-12B illustrate forming packages 900 using a chip on reconstructed wafer (CoRW) process. The utilization of a CoRW process allows for additional benefits from the binning processes described above. For example, these embodiments allow for greater selectivity in choosing the components for the semiconductor packages 900.

In FIGS. 8A-8C, semiconductor dies 600 are formed at wafer level as part of the wafer 650, similarly as described in connection with the semiconductor dies 100 and FIGS. 1A-1C. In addition, semiconductor dies 700 are formed at wafer level as part of the wafer 750, similarly as described above in connection with the semiconductor dies 200 and FIGS. 2A-2C. Note that analogous component features of the semiconductor dies 600, 700 may have like names and identification numbers as the semiconductor dies 100, 200 (respectively). Some aspects of the package 900 are formed similarly as the package 400 (described above). However, some differences include that the semiconductor dies 600, 700 will be singulated before being attached and incorporated into the package 900.

In accordance with various embodiments, chip probe tests are performed on each of the semiconductor dies 600, 700, similarly as described above in connection with the semiconductor dies 100, 200. In addition, a binning process may be performed to categorize the semiconductor dies 600, 700 based on the results of the chip probe tests, similarly as described above in connection with the semiconductor dies 100, 200. As such, the semiconductor dies 600, 700 are categorized as KGDs 600A, 700A, MPDs 600B, 700B, and KBDs 600C, 700C.

In addition, for the sake of example, each of the semiconductor dies 600, 700 may include, e.g., eight cores such that any number from 0 to 8 of the cores may be deemed functional. Further, the binning process may further include assigning an upper range of functional cores as pertaining to a KGD (e.g., 6 to 8 functional cores), an intermediate number of functional cores as pertaining to an MPD (e.g., 3 to 5 functional cores), and a lower range of functional cores as pertaining to a KBD (e.g., 0 to 2 functional cores).

FIGS. 8B and 8C illustrate exemplary plan views of the semiconductor dies 600 of the wafer 650 and the semiconductor dies 700 of the wafer 750, respectively. Note that the illustrations are simplified to distinguish between device regions containing each of the semiconductor dies 600, 700. In addition, the numbers of illustrated semiconductor dies 600, 700 are solely for the sake of example, and any suitable numbers may be included in the wafers 650, 750. In some embodiments, the MPDs 600B and the KBDs 600C may be scattered among a majority being the KGDs 600A, and similarly the MPDs 700B and the KBDs 700C may be scattered among a majority being the KGDs 700A. For example and for the sake of current and subsequent discussion, the KGDs 600A may represent about 80% of the wafer 650, the MPDs 600B may represent about 10% of the wafer 650, and the KBDs 600C may represent about 10% of the wafer 650. Similarly, the KGDs 700A may represent about 80% of the wafer 750, the MPDs 700B may represent about 10% of the wafer 750, and the KBDs 700C may represent about 10% of the wafer 750.

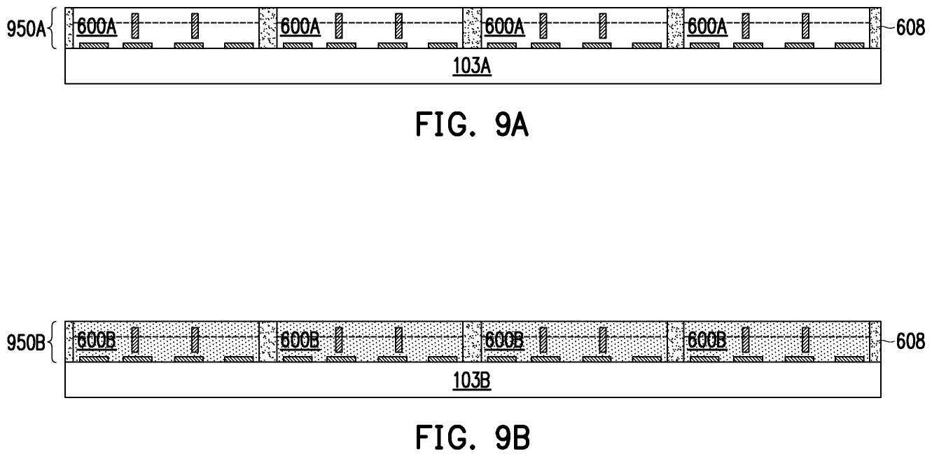

In FIGS. 9A and 9B, some of the semiconductor dies 600 are selected to form one or more wafers (e.g., wafers 950A, 950B). For example, the KGDs 600A may be selected to form semiconductor packages 900A that will be included in high performance electronic devices (e.g., servers). In addition, the MPDs 600B (and, optionally, some of the KGDs 600A) may be selected to form semiconductor packages 900B that will be included in medium performance electronic devices (e.g., gaming computers). In accordance with some embodiments, the semiconductor dies 600 are singulated, and the KGDs 100A are attached to a carrier substrate 103A. Similarly, the MPDs 100B may be attached to a carrier substrate 103B. After attachment, an insulating material 608 is formed between the semiconductor dies 600 to form reconstructed wafers 950 (e.g., wafers 950A, 950B), similarly as described above in connection with the insulating material 308.

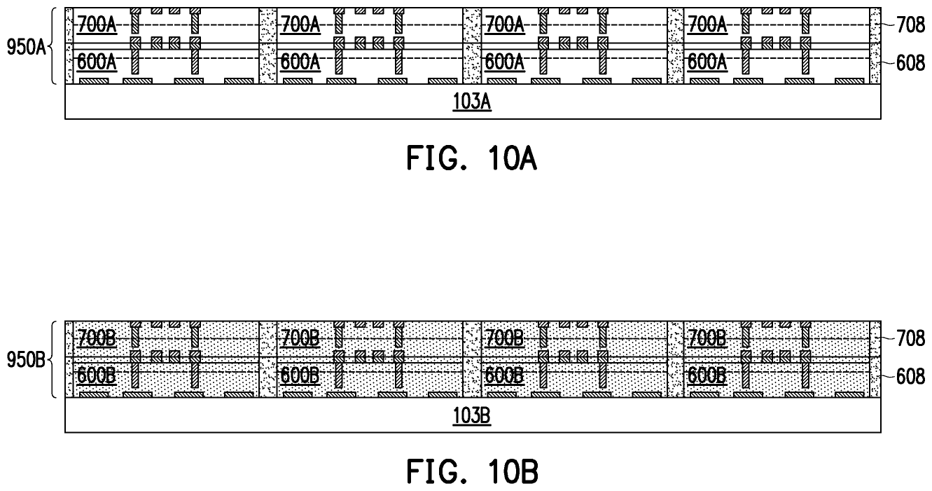

In FIGS. 10A and 10B, some of the semiconductor dies 700 are selected to be packaged in the semiconductor packages 900A, 900B. For example, the KGDs 700A may be selected to be incorporated into the semiconductor packages 900A, and the MPDs 700B may optionally be selected to be incorporated into the semiconductor packages 900B. Note that, based on performance needs and availability, other combinations of the semiconductor dies 600A, 600B with the semiconductor dies 700A, 700B may be utilized, similarly as the various combinations described above in connection with the semiconductor packages 400. In accordance with some embodiments, the semiconductor dies 700 are singulated, and the KGDs 700A are attached to the reconstructed wafer 950A. Similarly, the MPDs 700B may be attached to the reconstructed wafer 950B. After attachment, an insulating material 708 is formed between the semiconductor dies 700, similarly as described above in connection with the insulating material 308.

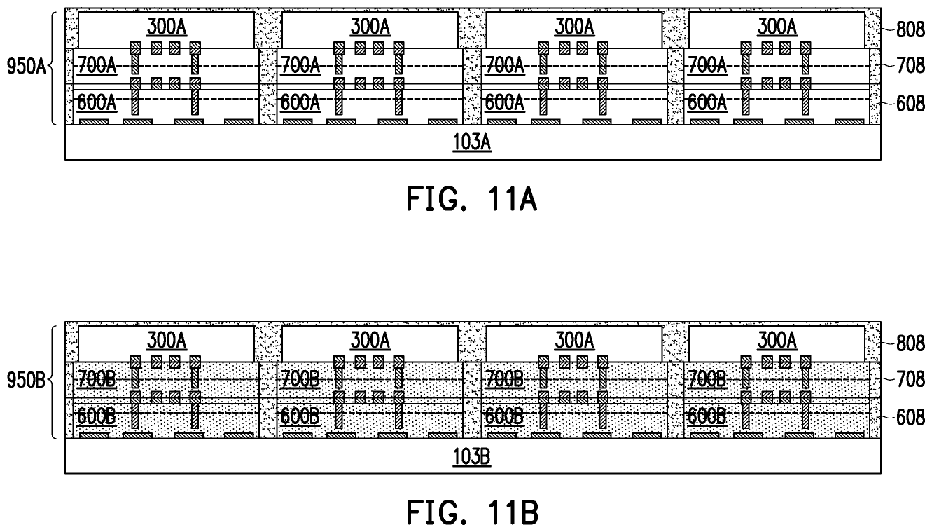

In FIG. 11, semiconductor dies 800 may be formed at a wafer level, singulated, and attached to the reconstructed wafer 950R. After attachment, an insulating material 808 is formed between the semiconductor dies 800, similarly as described above in connection with the insulating material 308.

In FIG. 12, carrier substrates 902A, 902B are attached, the carrier substrates 103A, 103B are removed, and external connectors 904A, 904B are formed along the semiconductor dies 100 (e.g., front-sides of the reconstructed wafers 950A, 950B).

Various advantages are achieved. In particular, the binning processes are utilized with the double tiered stack of semiconductor dies 100, 200 (or semiconductor dies 600, 700) in order to form semiconductor packages 400 (or semiconductor packages 900) with particular performance requirements. In addition, the binning processes allow for semiconductor dies 100, 200, 600, 700 that would otherwise fall below performance thresholds to be utilized in functional semiconductor packages 400, 900. Further, the binning processes provide predictive benefits which allow for customizations to other processing steps, including selection of other components of the semiconductor packages 400, such as the semiconductor dies 300.

In an embodiment, a method includes: forming first semiconductor dies in a first wafer, each die of the first semiconductor dies comprising: first active devices over a front-side of a first semiconductor substrate; and a first interconnect structure over the first active devices; performing first probe tests on the first wafer; based on the first probe tests, classifying each die of the first semiconductor dies as a first good die, a first marginal die, or a first bad die; forming second semiconductor dies in a second wafer, each die of the second semiconductor dies includes: second active devices over a front-side of a second semiconductor substrate; and a second interconnect structure over the second active devices; performing second probe tests on the second wafer; based on the second probe tests, classifying each die of the second semiconductor dies as a second good die, a second marginal die, or a second bad die; and bonding the second wafer to the first wafer, each die of the first semiconductor dies aligning with a corresponding die of the second semiconductor dies. In another embodiment, the first probe tests measure a first number of functional cores in each of the first semiconductor dies, wherein the first number determines a first classification for each of the first semiconductor dies. In another embodiment, the second probe tests measure a second number of functional cores in each of the second semiconductor dies, wherein the second number determines a second classification for each of the second semiconductor dies. In another embodiment, the method further includes determining a third classification for a first exemplary die of the first semiconductor dies and a corresponding second exemplary die of the second semiconductor dies. In another embodiment, each die of the first semiconductor dies further comprises a first through via extending from the front-side of the first semiconductor substrate and partially through the first semiconductor substrate, and wherein the method further includes: attaching a front-side of the first wafer to a carrier substrate; and removing a portion of the first semiconductor substrate to expose the through via. In another embodiment, bonding the second wafer to the first wafer comprises, after attaching the front-side of the first wafer to the carrier substrate: forming a first bond pad over the through via; and forming a direct metal-to-metal bond between the first bond pad and a second bond pad of the second wafer. In another embodiment, the method further includes: attaching a plurality of singulated third semiconductor dies to the second wafer; removing the carrier substrate; and forming external connectors along the front-side of the first wafer.

In an embodiment, a method includes: forming a first wafer comprising first semiconductor dies; performing first probe tests on the first semiconductor dies; performing a first binning process to categorize the first semiconductor dies as comprising first good dies, first marginal dies, and first bad dies; forming a second wafer comprising second semiconductor dies; performing second probe tests on the second semiconductor dies; performing a second binning process to categorize the second semiconductor dies as comprising second good dies, second marginal dies, and second bad dies; and forming a plurality of semiconductor packages, the plurality of semiconductor packages includes: a first high performance package comprising a first one of the first good dies and a first one of the second good dies; and a first marginal performance package comprising a first one of the first marginal dies and a first one of the second marginal dies. In another embodiment, the plurality of the semiconductor packages further comprises a first low performance package comprising a first one of the first bad dies and a first one of the second bad dies. In another embodiment, the plurality of the semiconductor packages further includes: a second high performance package comprising a second one of the first good dies and a second one of the second marginal dies; and a third high performance package comprising a second one of the first marginal dies and a second one of the second good dies. In another embodiment, the plurality of the semiconductor packages further includes: a second marginal performance package comprising a third one of the first good dies and a second one of the second bad dies; and a third marginal performance package comprising a second one of the first bad dies and a third one of the second good dies. In another embodiment, forming the plurality of the semiconductor packages comprises bonding the first wafer to the second wafer. In another embodiment, the first high performance package and the first marginal performance package are formed simultaneously in a same wafer and subsequently singulated from one another. In another embodiment, forming the plurality of the semiconductor packages comprises; forming a first reconstructed wafer comprising some of the first semiconductor dies; and attaching a first set of the second semiconductor dies to the first reconstructed wafer. In another embodiment, the first high performance package is formed in the first reconstructed wafer, and wherein the first marginal performance package is formed in a second reconstructed wafer being different from the first reconstructed wafer.

In an embodiment, a method includes: forming a first semiconductor die in a first wafer; performing a first binning process to assign a first category to the first semiconductor die; attaching a front-side of the first wafer to a first carrier substrate; forming a second semiconductor die in a second wafer; performing a second binning process to assign a second category to the second semiconductor die; bonding the second semiconductor die to the first semiconductor die; bonding a third semiconductor die of a plurality of dies to the second semiconductor die, the plurality of dies includes: sufficient performance dies; and insufficient performance dies, wherein attaching the third semiconductor die comprises selecting between the sufficient performance dies and the insufficient performance dies based on the first category of the first semiconductor die and the second category of the second semiconductor die. In another embodiment, the insufficient performance dies comprise dummy dies. In another embodiment, one of the sufficient performance dies is selected if at least one of the first category or the second category is above a predetermined performance threshold, and wherein one of the insufficient performance dies is selected if both the first category and the second category are below the predetermined performance threshold. In another embodiment, the first semiconductor die, the second semiconductor die, and the third semiconductor die combine to form a semiconductor package. In another embodiment, the method further includes a third binning process to assign the semiconductor package to a third category.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming first semiconductor dies in a first wafer, each die of the first semiconductor dies comprising:
first active devices over a front-side of a first semiconductor substrate; and
a first interconnect structure over the first active devices;
performing first probe tests on the first wafer;
based on the first probe tests, classifying each die of the first semiconductor dies as a first good die, a first marginal die, or a first bad die;
forming second semiconductor dies in a second wafer, each die of the second semiconductor dies comprising:
second active devices over a front-side of a second semiconductor substrate; and
a second interconnect structure over the second active devices;
performing second probe tests on the second wafer;
based on the second probe tests, classifying each die of the second semiconductor dies as a second good die, a second marginal die, or a second bad die; and
bonding the second wafer to the first wafer, each die of the first semiconductor dies aligning with a corresponding die of the second semiconductor dies.

2. The method of claim 1, wherein the first probe tests measure a first number of functional cores in each of the first semiconductor dies, wherein the first number determines a first classification for each of the first semiconductor dies.

3. The method of claim 1, wherein the second probe tests measure a second number of functional cores in each of the second semiconductor dies, wherein the second number determines a second classification for each of the second semiconductor dies.

4. The method of claim 3, further comprising determining a third classification for a first exemplary die of the first semiconductor dies and a corresponding second exemplary die of the second semiconductor dies.

5. The method of claim 1, wherein each die of the first semiconductor dies further comprises a first through via extending from the front-side of the first semiconductor substrate and partially through the first semiconductor substrate, and wherein the method further comprises:
attaching a front-side of the first wafer to a carrier substrate; and
removing a portion of the first semiconductor substrate to expose the through via.

6. The method of claim 5, wherein bonding the second wafer to the first wafer comprises, after attaching the front-side of the first wafer to the carrier substrate:
forming a first bond pad over the through via; and
forming a direct metal-to-metal bond between the first bond pad and a second bond pad of the second wafer.

7. The method of claim 6, further comprising:
attaching a plurality of singulated third semiconductor dies to the second wafer;
removing the carrier substrate; and
forming external connectors along the front-side of the first wafer.

8. A method, comprising:
forming a first wafer comprising first semiconductor dies;
performing first probe tests on the first semiconductor dies;
performing a first binning process to categorize the first semiconductor dies as comprising first good dies, first marginal dies, and first bad dies;
forming a second wafer comprising second semiconductor dies;
performing second probe tests on the second semiconductor dies;
performing a second binning process to categorize the second semiconductor dies as comprising second good dies, second marginal dies, and second bad dies; and
forming a plurality of semiconductor packages, the plurality of semiconductor packages comprising:
a first high performance package comprising a first one of the first good dies and a first one of the second good dies; and
a first marginal performance package comprising a first one of the first marginal dies and a first one of the second marginal dies.

9. The method of claim 8, wherein the plurality of the semiconductor packages further comprises a first low performance package comprising a first one of the first bad dies and a first one of the second bad dies.

10. The method of claim 8, wherein the plurality of the semiconductor packages further comprises:
a second high performance package comprising a second one of the first good dies and a second one of the second marginal dies; and
a third high performance package comprising a second one of the first marginal dies and a second one of the second good dies.

11. The method of claim 10, wherein the plurality of the semiconductor packages further comprises:
a second marginal performance package comprising a third one of the first good dies and a second one of the second bad dies; and
a third marginal performance package comprising a second one of the first bad dies and a third one of the second good dies.

12. The method of claim 8, wherein forming the plurality of the semiconductor packages comprises bonding the first wafer to the second wafer.

13. The method of claim 12, wherein the first high performance package and the first marginal performance package are formed simultaneously in a same wafer and subsequently singulated from one another.

14. The method of claim 8, wherein forming the plurality of the semiconductor packages comprises;
forming a first reconstructed wafer comprising some of the first semiconductor dies; and
attaching a first set of the second semiconductor dies to the first reconstructed wafer.

15. The method of claim 14, wherein the first high performance package is formed in the first reconstructed wafer, and wherein the first marginal performance package is formed in a second reconstructed wafer being different from the first reconstructed wafer.

16. A method, comprising:
forming a first semiconductor die in a first wafer;
performing a first binning process to assign a first category to the first semiconductor die;
attaching a front-side of the first wafer to a first carrier substrate;
forming a second semiconductor die in a second wafer;
performing a second binning process to assign a second category to the second semiconductor die;
bonding the second semiconductor die to the first semiconductor die;
bonding a third semiconductor die of a plurality of dies to the second semiconductor die, the plurality of dies comprising:
sufficient performance dies; and
insufficient performance dies, wherein attaching the third semiconductor die comprises selecting between the sufficient performance dies and the insufficient performance dies based on the first category of the first semiconductor die and the second category of the second semiconductor die.

17. The method of claim 16, wherein the insufficient performance dies comprise dummy dies.

18. The method of claim 16, wherein one of the sufficient performance dies is selected if at least one of the first category or the second category is above a predetermined performance threshold, and wherein one of the insufficient performance dies is selected if both the first category and the second category are below the predetermined performance threshold.

19. The method of claim 16, wherein the first semiconductor die, the second semiconductor die, and the third semiconductor die combine to form a semiconductor package.

20. The method of claim 19, further comprising a third binning process to assign the semiconductor package to a third category.
